(19) United States
(12) Patent Application Publication
(10) Pub. No.: US 2010/0096157 A1
(43) Pub. Date: Apr. 22, 2010

(54) FLUSH ELECTRICAL POWERPOINT DEVICE BOX

(76) Inventors: Joseph August Anton Diening, Toronto (CA); Nicholas Hansen McGowan, Toronto (CA)

Correspondence Address: GOWLING LAFLEUR HENDERSON LLP, SUITE 1600, 1 FIRST CANADIAN PLACE, 100 KING STREET WEST, TORONTO, ON, M5X 1G5, CA

(21) Appl. No.: 12/580,454

(22) Filed: Oct. 16, 2009

Related U.S. Application Data
(60) Provisional application No. 61/196,220, filed on Oct. 16, 2008.

(51) Int. Cl. H05K 5/00

(52) U.S. Cl. 174/53

(57) ABSTRACT

Disclosed is a below grade electrical power delivery device for powering auxiliary electrical equipment. The device comprises a container, a lid attached to the container, an electrical box attached to the interior surface of the lid and a terminal box attached to the interior of the container. A power supply is connected to the terminal box which in turn is connected to the electric box. The lid can be opened to reveal the electric box and to attach a cable to a receptacle in the electric box. There is also a drainage passage in the container and protective plates so as to protect the electrical equipment from water damage.

### RELATED APPLICATION

This application claims priority from provisional application no. 61/196,220, filed on Oct. 16, 2008.

### FIELD

The present invention relates generally to rest stop electrification and specifically to a below grade electrical device configured to provide an electrical outlet to vehicles at a rest stop.

### BACKGROUND

Many long-haul truck drivers idle their truck's engines during rest periods to provide temperature control for the sleeper compartment, keep the engine warm during cold weather, and generate electrical power for appliances.

Studies suggest that long-haul trucks often idle up to eight hours per day, over 300 days per year. Idling for such extended period of time consumes a significant amount of fuel as well as contributing to the emission of green house gases and other contaminants. Unnecessary engine idling also contributes to engine wear, which increases truck maintenance costs, and shortens engine life. Accordingly, it is understood that using a truck engine to power amenities is inefficient.

One solution proposed to reduce engine idling is truck stop electrification. Truck stop electrification allows trucks to use electrical power from an external source. At properly equipped truck stops, drivers can shut the main truck engine off and plug into an electrical outlet that provides power for heaters, air conditioners, marker lights, and other accessories. Trucks need to be equipped with the required internal wiring, inverter system, and heating, ventilation and air-conditioning (HVAC) system to take advantage of truck stop electrification.

An example of truck stop electrification is described in U.S. Pat. No. 6,482,080 issued to Wilson et al., titled “Apparatus for Providing Convenience Services to Stationary Vehicles”. The patent described a supply panel that is configured to interface with the vehicle through a window or a service door. The supply panel provides convenience services such as HVAC service, electrical power, telephone, video, television services and the like. The supply panel has at least one conduit attached thereto to provide the convenience services.

However, such a solution is expensive and difficult to implement. Further, more trucks are becoming equipped to provide there own services. For example, with the proliferation of wireless technology, many drivers have cellular telephones and notebook computers. Further, more trucks are being equipped with the required internal wiring, inverter systems, and HVAC systems to take advantage of an external power source.

Accordingly, there is a need for a simple solution to provide truck stop electrification that can provide truck drivers with the necessary electricity to power the truck's convenience services.

### SUMMARY

Accordingly, the present invention provides a subterranean electrical receptacle for installation at a vehicle rest area. The electrical receptacle provides an outlet configured for receiving a power cord from a vehicle.

In accordance with an aspect of the present invention, there is provided a below grade electrical power delivery device, comprising: a container having a top end opposite a bottom end; a movable lid having an interior surface, the lid movable between an open position and a closed position, the interior surface and container defining an interior a terminal box in the interior of the container, the terminal box for receiving electricity from a cable; and an electrical box in the interior of the container, the electrical box having a receptacle outlet for receiving a cable connection, wherein the receptacle outlet is accessible from without the interior when the lid is in its open position and the receptacle outlet is confined in the interior when the lid is in its closed position.

### BRIEF DESCRIPTION OF THE DRAWINGS

An embodiment of the invention will now be described by way of example only with reference to the following drawings in which:

FIG. 1 is a side plan cut-away view of the electrical power delivery device in accordance with an exemplary embodiment of the present invention;

FIG. 2 is a side plan cut-away view of the electrical power delivery device in accordance with an exemplary embodiment of the present invention;

FIG. 3 is an isometric view of the electrical power delivery device in accordance with an exemplary embodiment of the present invention;

FIG. 4 is a top plan view of the electrical power delivery device in accordance with an exemplary embodiment of the present invention;

FIG. 5 is a cross-sectional view of the lid of the electrical power delivery device along line B-B of FIG. 1;

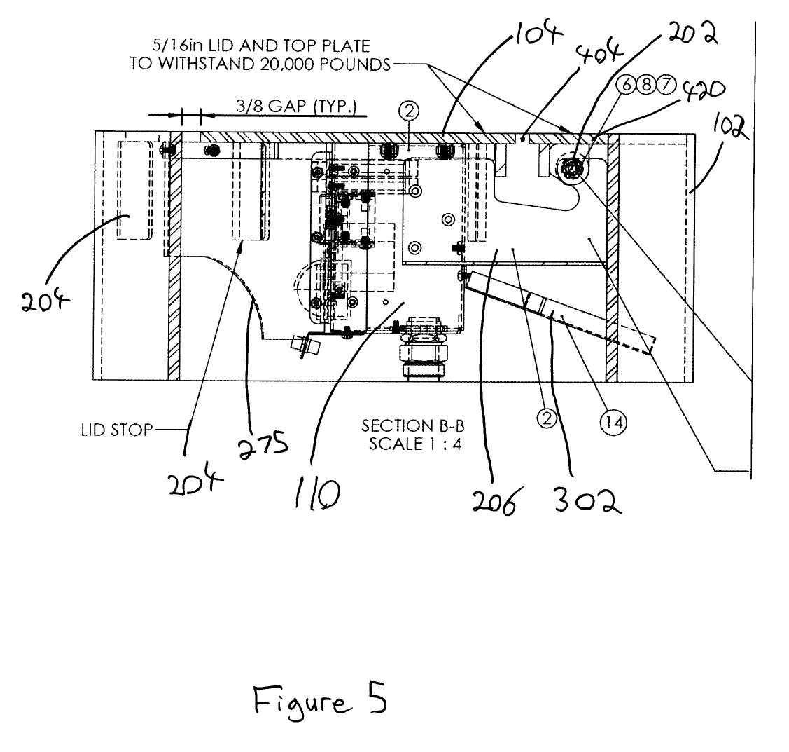

FIG. 6 is a front plan view of the lid of the electrical power delivery device in accordance with an exemplary embodiment of the present invention;

FIG. 7 is a side plan view of the lid of the electrical power delivery device in accordance with an exemplary embodiment of the present invention;

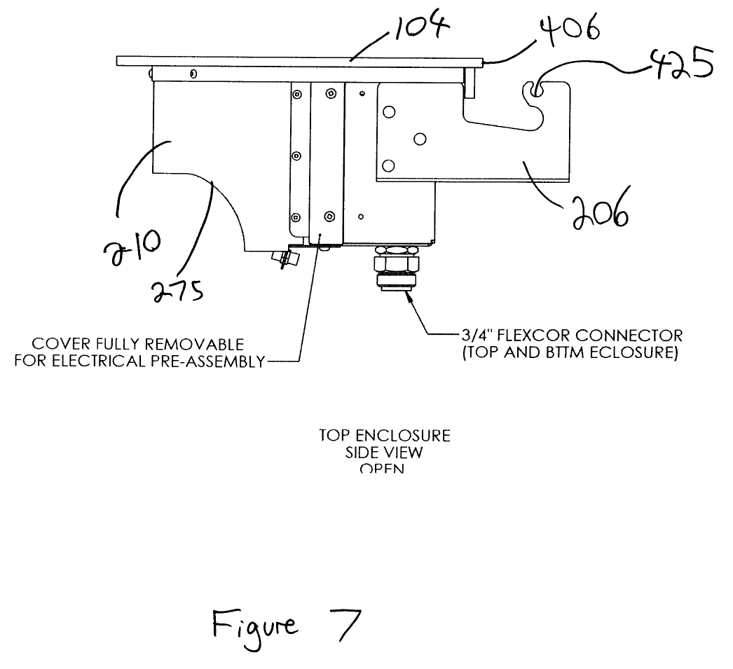

FIG. 8 is an isometric view of the lid of the electrical power delivery device in accordance with an exemplary embodiment of the present invention;

FIG. 9 is a front view of the terminal block of the electrical power delivery device in accordance with an exemplary embodiment of the present invention;

FIG. 10 is a side view of the terminal block of the electrical power delivery device in accordance with an exemplary embodiment of the present invention; and

FIG. 11 is an isometric view of the terminal block of the electrical power delivery device in accordance with an exemplary embodiment of the present invention.

### DETAILED DESCRIPTION OF THE PREFERRED EMBODIMENT

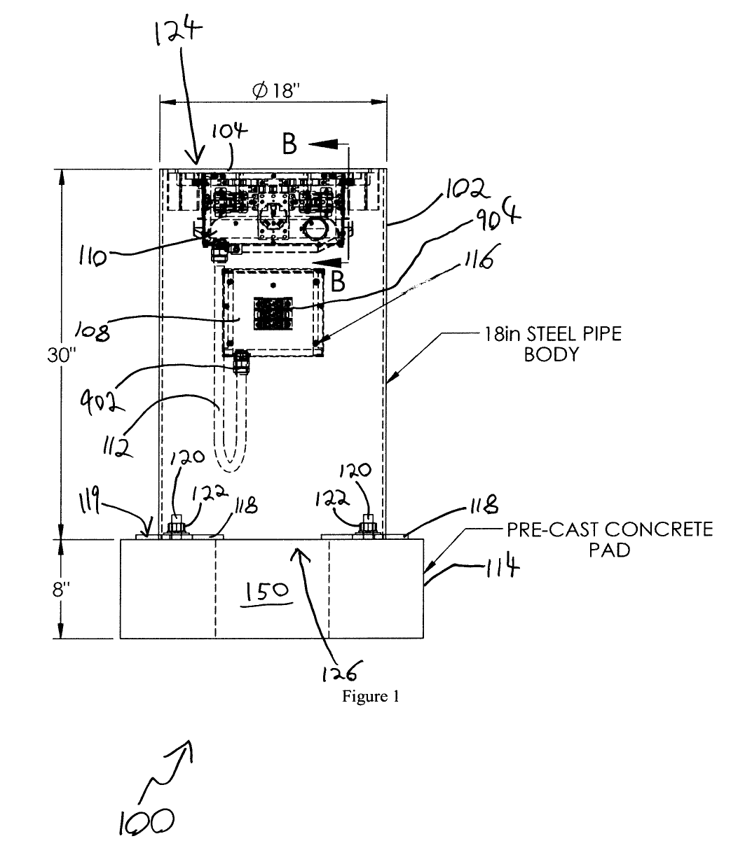

For convenience, like numerals in the description refer to like structures in the drawings. Referring to FIG. 1, a front view of a below grade outdoor electrical power delivery device is illustrated generally by numeral 100. The below grade outdoor electrical power delivery device 100 may be used for truckstop electrification for example.

The outdoor electrical power delivery device 100 may be used at a vehicle rest stop to provide auxiliary electrical power to vehicles. For example the electrical power delivery device 100 may be used at a truck stop to provide auxiliary electrical power to trucks. The outdoor electrical power device is below grade or subterranean so that it does not interfere with vehicle or truck wheels.

Referring to FIGS. 1 to 3, the electrical power device comprises a container 102 with a top end 124 and a bottom end 126. The bottom end 126 is connected to a pre-cast concrete pad 114 and the top end 124 is connected to a lid 104 all of which, together, define an interior with each of the container 102 and lid 104 having an interior surface facing the interior.

A terminal box 108 is connected to the interior surface of the container 102. An electrical box 110 is connected to the interior surface of the lid 104.

The container 102 shown in the Figures is cylindrical with a hollow interior. However it will be apparent to a skilled reader that the invention described herein can be used with a container 102 of a different shape such as a rectangular cuboid.

The container 102 may be made of steel or other suitable material known to a person of ordinary skill in the art. Suitable material includes material that can withstand the weight of a truck for example. For example the container 102 may be a steel pipe with a diameter of 18 inches (as shown in FIG. 1).

The bottom end 126 of the container 102 has a four legs 118 with each leg 118 having a planar surface 119. Each leg 118 is attached to the bottom of the container 102 such that the planar surfaces 119 of the legs 118 are at an angle perpendicular to the longitudinal axis of the container 102. The legs 118 (and their planar surfaces 119) extend outwardly and/or inwardly from the container 102 and are for attaching to a surface, such as the concrete pad 114. In the embodiments shown, nuts 122 and bolts 120 extend through the planar surfaces 119 and into the concrete pad 114 with one pair of nut 122 and bolt 120 for each planar surface 119. The legs 118 and hence container 102 are thereby secured to the concrete pad 114. It will be apparent to a person of ordinary skill in the art that alternative means of attaching the container 102 to a surface can be substituted with the nuts 122 and bolts 120 arrangements explained above without departing from the scope of the invention.

The concrete pad 114 may be secured or formed or cast in the ground first before securing the container 102 to the concrete pad 114. However, it is not essential that these steps be performed in this sequence; the container 102 can be secured to the concrete pad 114 before the concrete pad 114 is placed into the ground. Additionally, the concrete pad 114 may be placed in the ground such that when the container 102 is secured to the pad 114 the top end 124 of the container 102 is flush with the ground. Thus, the interior of the container 102 is “below grade” but the container is visible and provides no significant obstacle to vehicles passing there over. The concrete pad 114 has an aperture 150 therethrough underneath the bottom end 126 of the container 102. The aperture 150 forms a fluid channel with the interior of the container 102. There may be additional holes through the concrete pad 114.

The terminal box 108 is connected to the interior surface of the container 102 by a screw 116. A person of ordinary skill in the art would understand that alternative means of connection may be used to secure the terminal box 108 to the interior surface of the container 102. In the embodiments shown, the terminal box 108 is attached at the midsection of the container 102 (with respect to the longitudinal height of the container 102). It is recognized that this invention may operate equally well with the terminal box 108 attached to other locations in the interior of the container 102.

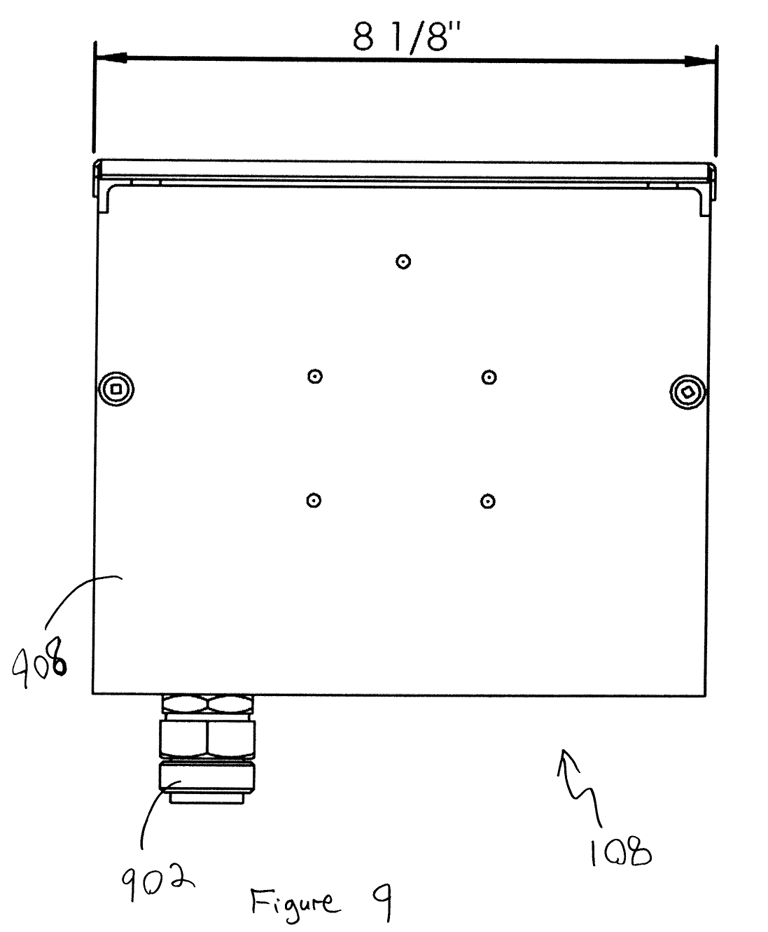

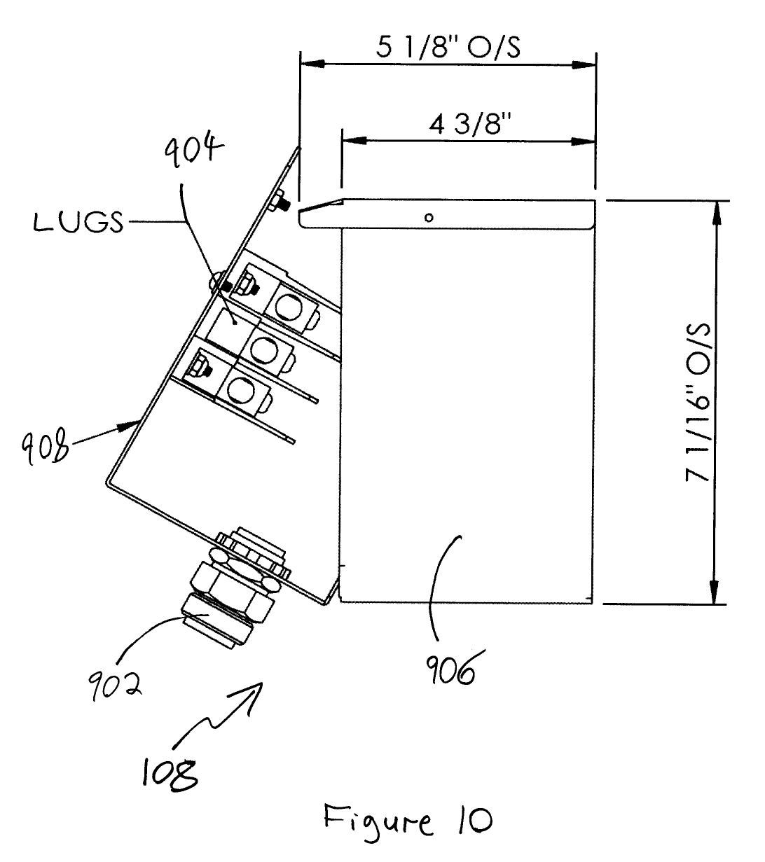

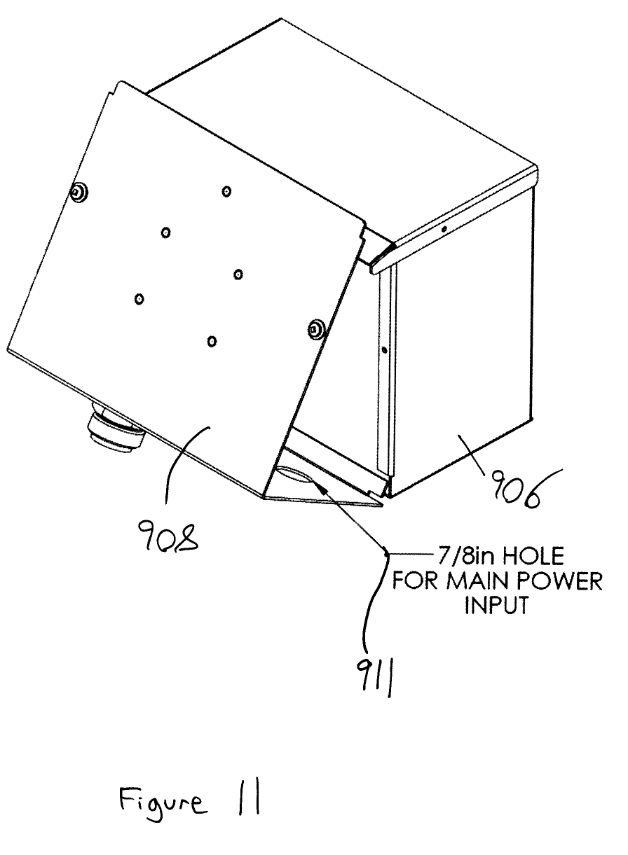

Referring to FIGS. 9 to 11, the terminal box 108 comprises a rectangular metallic casing 906, which is attached at one side to the interior surface of the container 102. The opposite side of the casing 906 is open. A cover 908 is removabley attached to the open side of the casing 906. The cover 908 may be fully removable from the casing 906 and/or attached by screws or other suitable attachment means. In an alternative embodiment the cover 908 may be attached by a hinge to the casing 906. FIGS. 10 and 11 show the cover 908 in an open position. Distribution lugs 904 and a cable outlet 902 are secured to the cover 908. There is also a hole 911 in the cover 908 for allowing a cable to pass through.

According to an embodiment, an underground cable (not shown) from a standard or conventional power grid passes through the aperture 150 in the concrete slabs 114 and connects to internal circuitry (not shown) of the terminal box 108. Additional underground cable such as coaxial cable, Ethernet cable and copper twisted pair cable, for example, may also connect to the internal circuitry. By way of further example, the additional underground cable (e.g. coaxial cable, Ethernet cable or copper twisted pair cable) can either be modified by the electronics used to implement the internal circuitry or merely pass through the internal circuitry. Power from the grid (e.g. from the additional underground cables) can be multiplexed from a plurality of different power lines having varying voltages and currents. The distributions lugs 904 provide access points to the different power lines provided by the internal circuitry. Further, there may be an aperture in the side of the container for allowing an underground cable from a standard or conventional power grid to pass through.

The electronics used to implement the internal circuitry are well known in the art and are not discussed in further detail to avoid detracting from the invention. Further, as will be appreciated, the number of different power lines as well as the corresponding voltage and current levels will vary depending on the implementation.

An interior conduit 112 couples the terminal box 108 to the electrical box 110. The interior conduit 112 provides a water resistant shell for covering any cables connected between the terminal box 108 and the electrical box 110. Alternately, the interior conduit 112 may be replaced by a multi-purpose cable, having the necessary connections, wiring and interfaces to “plug-in” to the terminal box 108 to the electrical box 110.

The electrical box 110 is secured to the interior surface of the lid 104. The electrical box 110 includes an interface for providing a user with access to the components provided. In the present embodiment, the electric box 108 interface contain the following components: a breaker 20 Amp, 1 Phase front mount; a receptacle outlet, 120 V, 20 Amp, GFI; a breaker 30 Amp, 1 Phase front mount; a receptacle outlet 120 V, 30 Amp A 3 Wire; a cable TV connector; a breaker 15 Amp 1 Phase, front mount; a receptacle outlet 120 V, 1 Phase, front mount; and a night light, 120 V. It will be appreciated that the components may vary depending on the requirements of the implementation. Accordingly, the receptacle outlets are configured for receiving a connecting power cable. The connecting power cable comes from the user and couples a load external to the electrical power delivery device 100.

A cover plate 210 extends inward from the interior surface of the lid 104 in a direction perpendicular to the plane of the lid 104. The cover plate 210 surrounds the front and sides of the electrical box 108. The cover plate 210 is removably attached to the lid 104 using screws or other suitable attachment means known to a person skilled in the art. Two hinge plates 206 are attached at one end by hinges 202 to the interior surface of the container 102. The opposite end of each hinge plate 206 attaches to the cover plate 210 on each side of the electric box 108. The lid 104 is thereby hingedly secured to the container 102. The cover plate 210 may be made of a rubber compound.

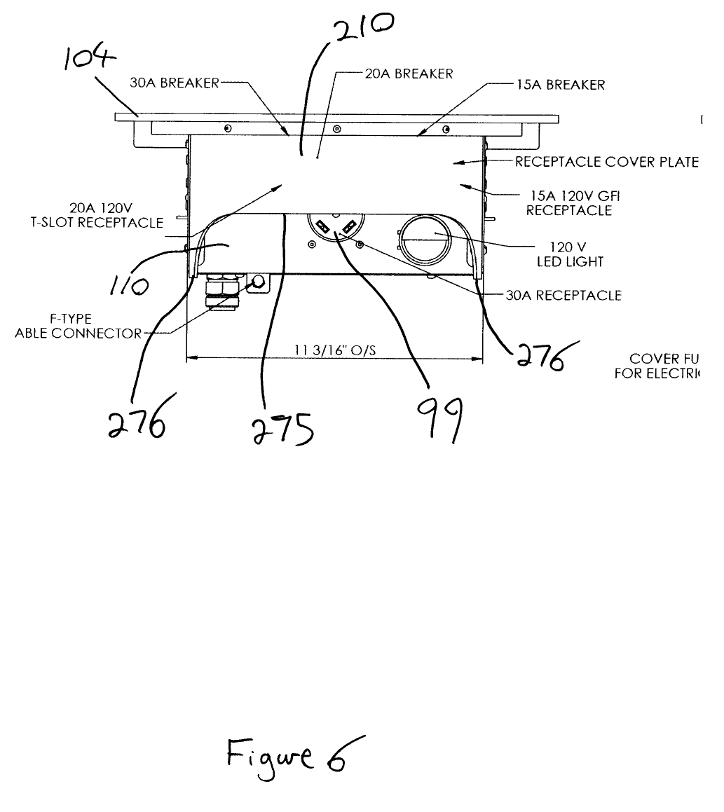

The cover plate 210 has a curved edge 275 opposite the interior surface of the lid 104. Referring to FIG. 6, the curved edge 275 extends between two ends 276. The curved edge 275 defines a parabola extending upwards (in the direction of the interior surface of the lid 104) from the two ends 276 thereby revealing a portion of the electrical box interface.

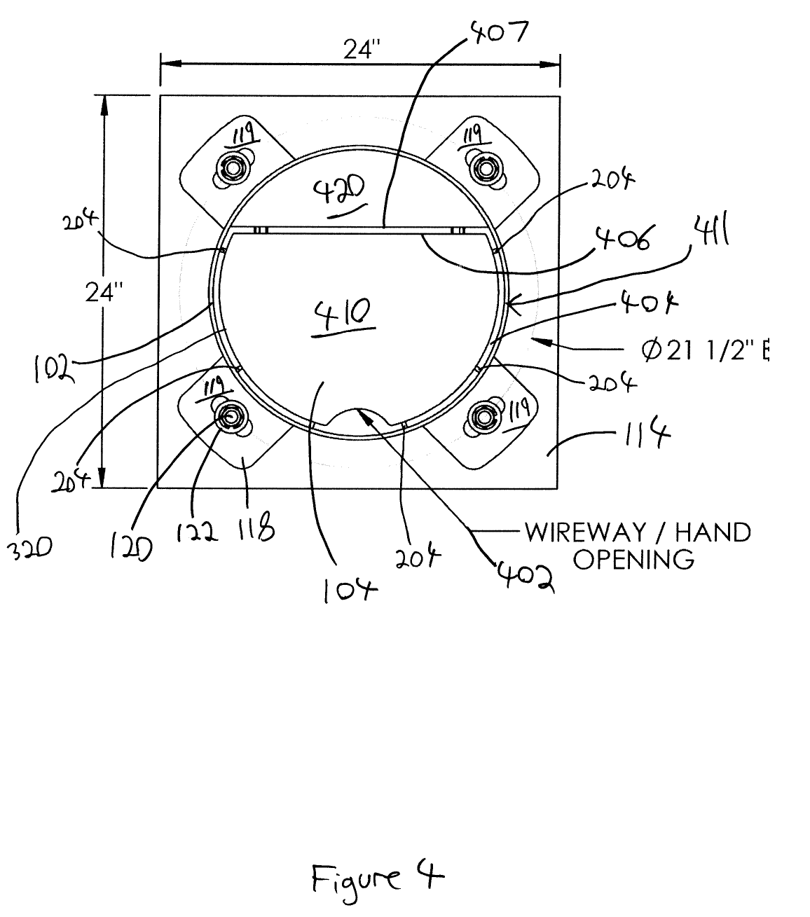

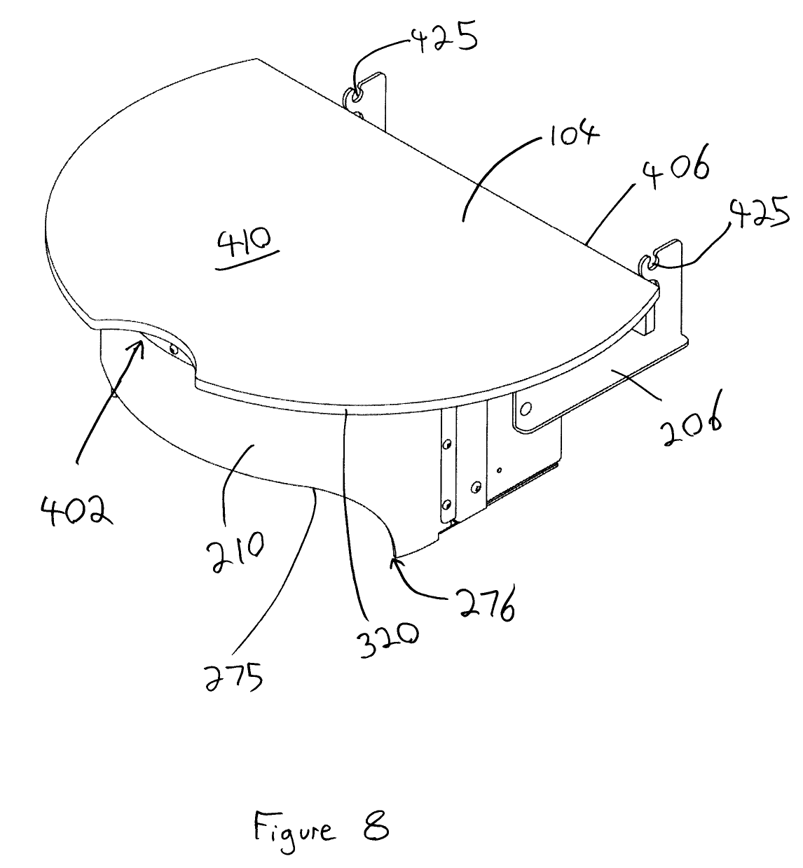

The lid 104 will now be described in more detail. Referring to FIGS. 4, 6 and 8, the upper surface 410 of the lid 104 defines a circle with one flat edge 406 extending between the two hinge plates 206. There is a notch 402 in the edge of the upper surface 410 of the lid 104 opposite the flat edge 406. The hinge plates 206 are attached on the interior surface of the lid 104 and extend in a direction parallel to the lid surface 410 beyond the flat edge 406 ending in the hinge attachments 425.

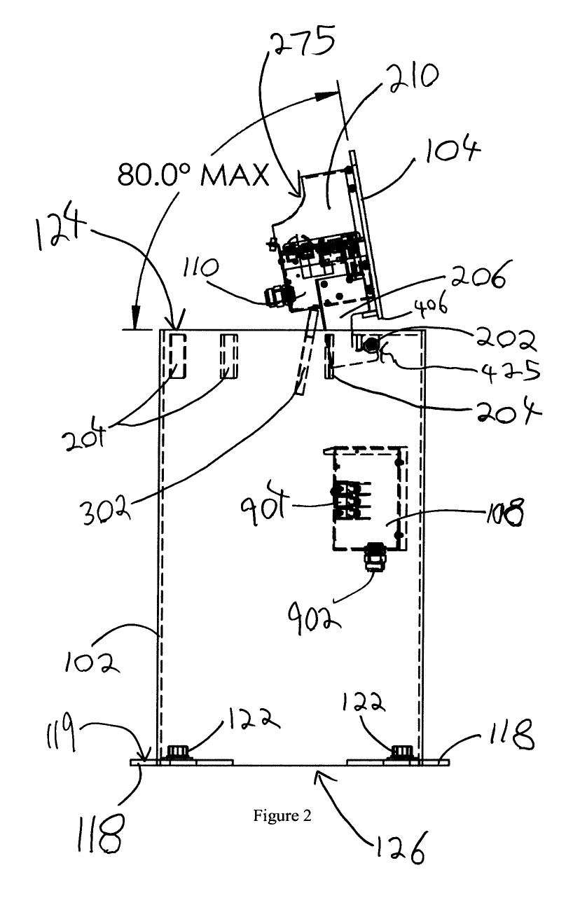

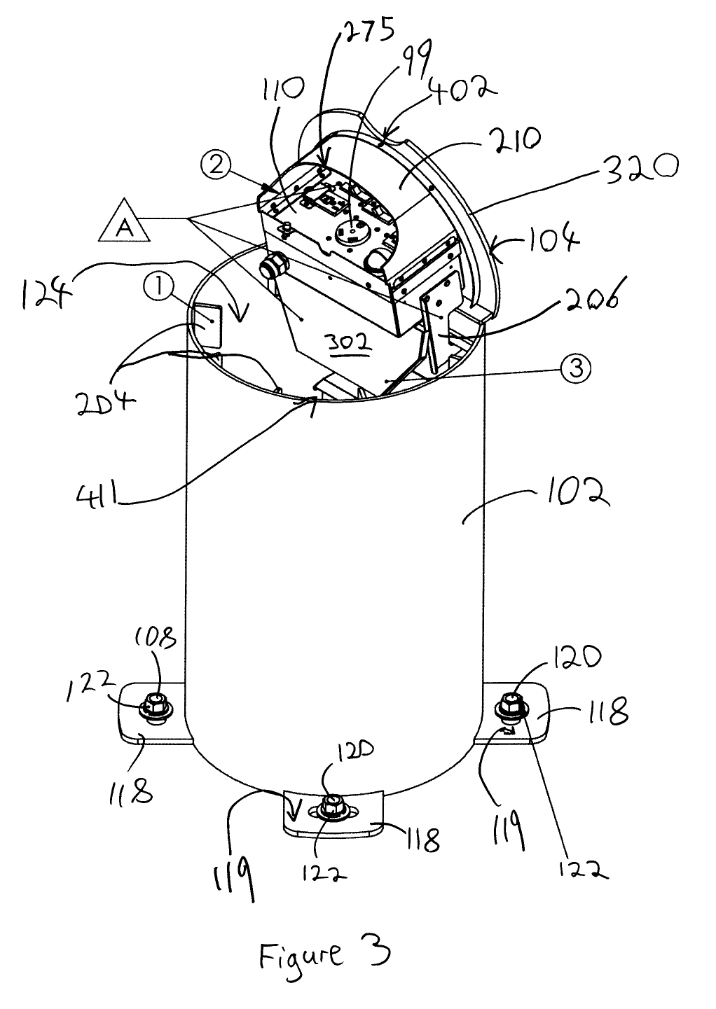

Referring to FIGS. 2 and 3, the hinge attachments 425 (and hence the hinge plates 206 and lid 104) are attached to hinges on the interior surface of the container 102. Alternatively the hinge attachments 425 may be attached to hinges on the interior surface of the metal plate 420. Alternatively, the plate 420 may be made of a rubber compound. As will be recognized by a person of ordinary skill in the art, the lid 104 may be secured by an alternative suitable means to the container 102 which will allow the lid 104 to be open (at least partially revealing the interior of the container) and closed.

In an embodiment, shown in FIG. 2, the lid 104 configured to open to a maximum of 80 degrees in relation to the top end 124 of the lid 104. In this way the lid 104 will be biased to the closed position (i.e. abutting the lid stops 204). Alternatively, a spring or other biasing mechanism can be used to bias the lid 204 to the closed position. Further, the lid 204 may not be biased at all to the closed position.

In an embodiment, the hinge attachments 425 are configured to break or shear upon impact. Thus, if for some reason the lid 104 is left in an open position and is contacted by a vehicle, the lid will break of at the hinge attachments 425, reducing potential damage to the electronics 108 and 110 and the below-grade container 102.

When the hinge attachments 425 (and hence the hinge plates 206 and lid 104) are hingedly attached to the container, the hinge attachments 425 and a portion of the hinge plates 206 are on the interior surface of the metal plate 420.

The interior of the container has six lid stops 204 near the container's top end 124. The lid stops 204 abut the lid 104 when the lid 104 is closed over the top end 124 of the container 102, thereby inhibiting the lid 104 from passing into the interior of the container 102. The lid stops 204 may be rectangular pieces of steel welded to or otherwise attached to the interior of the container 102 extending in the direction of the central axis of the cylindrical container 102. A person of skill in the art would recognize that other suitable stoppers which perform the function of preventing the lid 104 from passing beyond the stoppers into the interior of the container 102.

Opposing ends of a splash plate 302 are each secured to the hinge plates 206 (see FIG. 3). Alternatively, the splash plate 302 may be attached to the electrical box 110. Thus, when the lid 104 is closed over the top end 124 of the container 102, the splash plate 302 hangs above the terminal box 108 between the terminal box 108 and the top end 124 of the container 102.

The top end 124 of the container defines an opening in the shape of a circle. The periphery 411 of the circle defined by the opening is on a single plane. A planar metal sheet 420 extends inwardly (i.e. towards the centre of the circular opening) from the periphery 411 along the same plane as the periphery 411 (i.e. perpendicular to the longitudinal axis of the container 102) towards its edge 407. The edge 407 of the planar metal sheet 420 defines a chord on the circular opening of the top end 124 of the container.

The opening at the top end 124 of the container 102 defined by both the circular periphery 411 and the edge 407 of the metal sheet 420 outlines the shape defined by the edge 320 of the lid 104. However, the shape defined by the edge 320 of the lid 104 is slightly smaller than the shape defined by both the circular periphery 411 and the edge 407 of the metal sheet 420. Thus a gap 404 exists between the lid 104 and the container 102 at the top end 124 of the container 102.

The entire device 100 is then placed into the ground such that the top end 124 is substantially coplanar with the ground. In an embodiment the device 100 is placed into the ground at a truck stop.

If it rains, the water will pass through the gap 404 into the container 102 and through the aperture 150 in the concrete pad 114 into a drain. The cover plate 210 substantially blocks the water from going onto the interface of the electric box 110. Similarly, the splash plate 302 substantially blocks liquid or water from splashing or running or dripping onto the terminal box 108. Thus, water will not likely damage the electronic equipment contained in the device.

In operation, a vehicle (e.g. a truck) drives near the device 100. A person can then grasp the lid 104 using the notch 402 and rotate the lid 104 open around the hinge axis, thereby revealing the interior of the container 102. The person can then plug the external power cable (not shown) into a receptacle 99 on the interface and close the lid 104. When the lid 104 is closed the external power cable runs outside of the interior of the container through the notch 402 so that the lid 104 can close. With the lid 104 closed the external power cable extends through the notch 402.

The power from the grid going into the terminal box 108 is passed through the receptacle into the external power cable. The user can then use the electricity from the external power cable to power certain electronic devices (e.g. a radio) in his or her vehicle.

The electricity consumed through the device may be recorded by a third party and the user may then be able to pay that third party for the amount of electricity consumed. Alternatively, the user may pay a flat rate fee for access to the device. Billing schemes for electricity are well known in the art and continue to develop, but are beyond the scope of the invention.

Although the previous embodiment described truck stops, it will be appreciated by a person of ordinary skill in the art that the below-grade container 102, as described herein may have other applications. For example, the container 102 may be implemented in parking lots to provide power to electric vehicles. By way of further example, the container 102 may be implemented and/or used in a Recreational Vehicle park, in an underground parking garage, in a person's driveway or house garage, on the side of the street, etc. A person of ordinary skill in the art would recognize that the container 102 may be implemented and/or used anywhere a vehicle may park or rest in an idle state.

One or more currently preferred embodiments have been described by way of example. It will be apparent to persons skilled in the art that a number of variations and modifications can be made without departing from the scope of the invention as defined in the claims.

What is claimed is the following:

1. A below grade electrical power delivery device, comprising:
a container having a top end opposite a bottom end;
a movable lid having an interior surface, the lid movable between an open position and a closed position, the interior surface and container defining an interior;
a terminal box in the interior of the container, the terminal box for receiving electricity from a cable; and
an electrical box in the interior of the container, the electrical box having a receptacle outlet for receiving a cable connection,
wherein the receptacle outlet is accessible from without the interior when the lid is in its open position and the receptacle outlet is confined in the interior when the lid is in its closed position.

2. The below grade electrical power delivery device of claim 1, the terminal box attached to the interior surface of the container.

3. The below grade electrical power delivery device of claim 1, the electric box connected to the interior surface of the lid.

4. The below grade electrical power delivery device of claim 1, the lid hingedly attached to the container between the open position and the closed position.

5. The below grade electrical power delivery device of claim 1, the lid having a notch to allow a cable to pass therethrough when the lid is in the closed position.

6. The below grade electrical power delivery device of claim 1, wherein the lid is biased to the closed position.

7. The below grade electrical power delivery device of claim 1, wherein the container is cylindrical.

8. The below grade electrical power delivery device of claim 1, wherein the container is made of steel.

9. The below grade electrical power delivery device of claim 1, wherein the bottom end is attached to a concrete pad.

10. The below grade electrical power delivery device of claim 1, wherein a cable is attached to the terminal box for providing electricity from an electricity grid.

11. The below grade electrical power delivery device of claim 1, wherein the contour of the lid and the periphery of the top end of the container define a gap for allowing liquid to pass through.

12. The below grade electrical power delivery device of claim 11, further comprising a cover plate extending from the interior surface of the lid, the cover plate for inhibiting liquid from contacting the electric box.

13. The below grade electrical power delivery device of claim 11, further comprising a splash plate attached to at least one of the lid, container or electric box, the splash plate extending into the interior of the container, the splash plate for inhibiting liquid from contacting the terminal box.

14. The below grade electrical power delivery device of claim 11, wherein the bottom end of the container defines an aperture for allowing liquid to pass therethrough.

15. The below grade electrical power delivery device of claim 1, wherein the lid is positioned below grade so that the lid is flush with the surface of the ground when in the closed position.

16. The below grade electrical power delivery device of claim 7, wherein the device is in a truck stop.
